(19) United States
(12) Patent Application Publication
(10) Pub. No.: US 2010/0201493 A1
(43) Pub. Date: Aug. 12, 2010

(54) PHOTOELECTRIC CELL DEVICE AND MALFUNCTION DETERMINING METHOD

(76) Inventor: Hiroaki TAKANO, Saitama (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/699,498

(22) Filed: Feb. 3, 2010

(30) Foreign Application Priority Data
Feb. 10, 2009 (JP) P2009-028434

(51) Int. Cl. H04Q 5/22; H01L 27/144

(52) U.S. Cl. 340/10.1; 250/208.2

(57) ABSTRACT

Provided is a photoelectric-cell device including a power-source unit arranged between a ground line and a power-source line for generating photo-electromotive force and applying state information to the power-source line, and also including an inverter for converting a direct-current power source into a predetermined one and communicating with the unit via the power-source line. A power-source module of the unit includes a photoelectric-cell module, a bypass diode, a state detector, a communication unit, and a communication controller. The photoelectric-cell module includes cells for generating photo-electromotive force, first/second terminals on the ground-line/power-source-line sides, respectively. The anode of the diode is connected to the first terminal, and the cathode to the second terminal. The detector detects a state of each power-source module. The communication unit applies the information to the power-source line. The controller controls the communication unit to apply the information selectively, based on an information request from the inverter.

### BACKGROUND OF THE INVENTION

1. Field of the Invention

The present invention relates to a photoelectric device and a malfunction determining method.

2. Description of the Related Art

In recent years, photoelectric cell devices have become more and more important for power supply with less concern in depletion of the source nor in effect on the global environment, as compared with fossil fuels, upon which people have been dependent. By use of the photoelectric effect, Photoelectric cell devices can convert incident light directly into electricity, thereby they can supply cleaner power than fossil fuels do.

For example, a photoelectric cell device derives power, including therein a plurality of power source units arranged in parallel between a ground line and a power source line. Each of the power source units includes power source modules, each of which includes a photoelectric cell module for generating photo-electromotive force from incident light. In each power source unit, a plurality of power source module may be arranged into some sets to be connected in series to each other within the sets. So arranged power source units are said to be arranged in the series formation. And for example, a photoelectric cell module includes a plurality of cells for generating photo-electromotive force based upon incident light. These cells may be connected to each other in series and/or in parallel.

When a power source module included in a power source unit of a photoelectric cell device is broken, it can be relatively easily found that there has arisen a malfunction, by a fall in resulting power, for example. However, it is not easy to detect which power source module in the photoelectric cell device is broken because it may require measuring an open voltage, a short-circuit current, etc., for each power source module, for example. Such measurement could be difficult to be achieved since power source units of the photoelectric cell device may be placed on a roof, for example, to generate photo-electromotive force from the sunlight.

In such circumstances, techniques have been developed for facilitating detection of malfunctions in power source modules of a photoelectric cell device. For example, there is described in JP 2000-269531 (A) a technique for investigating and confirming malfunction in each power source module, based upon the results of detecting a signal at a frequency uniquely assigned to each power source module. In JP 2000-269531 (A), there is also described a technique for informing, through a dedicated line connected to each power source module, of information that indicates the state of each power source module included in a photoelectric cell device.

### SUMMARY OF THE INVENTION

Malfunction in a power source module is investigated and confirmed, based upon the results of detecting a signal at a frequency unique to the power source module, according to the typical technique (referred to as the “typical technique 1” hereinafter), by which each power source module is determined whether to be broken, based upon the results of detecting a signal at a frequency uniquely assigned to each power source module. According to the typical technique 1, a signal at a frequency unique to each power source module (referred to as a “unique frequency signal” hereinafter) is applied to a power source line, issued for each power source module by an oscillator circuit. Malfunction is investigated and confirmed, according to the typical technique 1 utilising such oscillator circuits, which stop oscillating for unique frequency signals when power supplies thereto are interrupted.

If, as in the typical technique 1, unique frequencies are respectively assigned to power source modules included in a photoelectric cell device to determine the power source modules whether to be broken, respectively, each of the frequencies should not be assigned to multiple power source modules. Thus, according to the typical technique 1, frequencies should be provided at least as many as the number of the power source modules. Furthermore, the more the number of the power source modules becomes, the more difficult it becomes to determine which power source module is broken. In addition, according to the typical technique 1, it may be difficult to detect what malfunction has arisen in a power source module determined as broken (e.g., malfunctions of short/open-circuit) because the power source has been determined to be broken, merely based upon the results of detecting the unique frequency signal for the power source module.

According to the typical technique (to be referred as to the “typical technique 2” hereinafter) for sending information of the state of each power source module through a dedicated line connected to each power source module, information of state is collected for each power source module. Thus, according to the typical technique 2, it could be still possible to detect what malfunction has arisen in power source modules determined as broken.

However, according to the typical technique 2, in order to detect malfunction for each power source module, information of state sent from each power source module one after another should be identified by which power source module it corresponds to. A power source module to which particular information of state corresponds will be identified by a unique frequency signal uniquely provided for the power source module or by a pulse signal of a pattern uniquely given for the power source module, for example, according to the typical technique 2. In the case of identification by use of different frequencies, according to the typical technique 2, frequencies should be provided at least as many as the number of the power source modules. Accordingly, the more the number of the power source modules becomes, the more difficult it becomes to determine which power source module is broken. In the case of identification by use of pulse signals of different patterns given for different power source modules, according to the typical technique 2, the more the number of the power source modules becomes, the more patterns should be given. However, the number of the pattern is limited. Accordingly, the number of the power source modules that the photoelectric cell device can include would be limited in this case of identification by use of pulse signals of different patterns given for different power source modules, according to the typical technique 2. Furthermore, in this case of identification by use of pulse signals of different patterns given for different power source modules, according to the typical technique 2, the more the number of the power source modules becomes, the more difficult it becomes to determine which power source module is broken.

As described above, according to the typical techniques 1 and 2 (referred as to the “typical techniques” hereinafter), various advantages might be found in detection of malfunction on the basis of information sent one after another from each power source included in a photoelectric cell device. Thus, it is not assured that detection of malfunction can be conducted for each power source module with the typical techniques.

In light of the foregoing, it is desirable to provide a photoelectric cell device and a malfunction determining method, which are novel and improved, and which can achieve an easy detection of malfunction in power source modules.

According to an embodiment of the present invention, there is provided a photoelectric cell device including a power source unit arranged between a ground line and a power source line for generating an photo-electromotive force from incident light and applying, to the power source line, state information which indicates a state, and also including an inverter for converting a direct-current power source applied from the power source line into a predetermined power source and communicating with the power source unit via the power source line. The power source unit includes one or more power source modules, each of which includes a photoelectric cell module including cells arranged in series and/or in parallel for generating the photo-electromotive force from the incident light, a first terminal on a side of the ground line, and a second terminal on a side of the power source line. Each of the one or more power source modules also includes a bypass diode having an anode and a cathode. The anode is connected to the first terminal of the photoelectric cell module, and the cathode is connected to the second terminal of the photoelectric cell module. Each of the one or more power source modules also includes a state detector for detecting a state of the each of the power source modules and outputting the detected state as a detection result, a communication unit for receiving an information request from the inverter and applying the state information based on the detection result to the power source line, and a communication controller for controlling the communication unit to apply the state information selectively, based on the information request received by the communication unit.

According to such an arrangement, detection of malfunction in power source modules can be facilitated.

The communication controller may have first identification information stored therein for uniquely representing the each of the one or more power source modules, and control the communication unit to transmit the state information if the first identification information matches second identification information specifying one or more of the one or more power source modules requested to transmit the state information. The second identification information may be contained in the information request.

The communication controller may control the communication unit not to transmit the state information if the first identification information does not match the second identification information.

The communication unit may include a transformer having a primary coil arranged to connect to the communication controller and a secondary coil arranged between the second terminal and the power source line or between the first terminal and the ground line.

The communication unit may include a transformer having a primary coil arranged to connect to the communication controller and a secondary coil arranged to connect to the ground line and the power source line.

The communication controller may be powered by the photoelectric cell module.

The communication controller is powered by each one or more of the cells included in the photoelectric cell module.

According to another embodiment of the present invention, there is provided a malfunction determining method including the step of transmitting an information request to a power source unit in order to acquire state information which indicates a state. The power source unit is arranged between a ground line and a power source line for generating photo-electromotive force from incident light. The power source unit includes one or more power source modules, each of which selectively applies the state information to the power source line on a basis of the information request. The malfunction determining method also includes the step of determining a state of the each of the one or more power source module, based on the state information selectively applied to the power source line.

By use of such a method, detection of malfunction in power source modules can be facilitated.

According to the embodiments of the present invention described above, detection of malfunction in power source modules can be facilitated.

### BRIEF DESCRIPTION OF THE DRAWINGS

FIG. 1 is the first illustration for illustrating the state of a power source module according to the embodiments of the present invention.

FIG. 2 is an illustration that shows an example of the characteristic of a cell included in a photoelectric cell module of the power source module according to the embodiments of the present invention.

FIG. 3 is an illustration that shows an example of the characteristic of a bypass diode.

FIG. 4 is the second illustration for illustrating the state of the power source modules according to the embodiments of the present invention.

FIG. 5 is the third illustration for illustrating the state of the power source modules according to the embodiments of the present invention.

FIG. 6 is the forth illustration for illustrating the state of the power source modules according to the embodiments of the present invention.

FIG. 7 is an illustration that shows an example of the arrangement of an photoelectric cell device according to the embodiments of the present invention.

FIG. 8 is an illustration that shows the first exemplary arrangement of the power source module according to the first embodiment of the present invention.

FIG. 9 is an illustration that shows an exemplary arrangement of a state detector according to the embodiments of the present invention.

FIG. 10 is an illustration that shows an exemplary arrangement of a communication controller included in the power source module according to the embodiments of the present invention.

FIG. 11 is an illustration that shows the second exemplary arrangement of the power source module according to the first embodiment of the present invention.

FIG. 12 is an illustration that shows the third exemplary arrangement of the power source module according to the first embodiment of the present invention.

FIG. 13 is an illustration that shows an example of malfunction determining method of the photoelectric cell device according to the embodiments of the present invention.

### DETAILED DESCRIPTION OF THE EMBODIMENT(S)

Hereinafter, preferred embodiments of the present invention will be described in detail with reference to the appended drawings. Note that, in this specification and the appended drawings, structural elements that have substantially the same function and structure are denoted with the same reference numerals, and repeated explanation of these structural elements is omitted.

The descriptions will be presented hereinafter in the order of:

### 1. Approach According to Embodiments of Present Invention;

### 2. Photoelectric Cell Device According to Embodiments of Present Invention; and

### 3. Malfunction Determining Method According to Embodiments of Present Invention.

### (Approach According to Embodiments of Present Invention)

Before the explanation of the photoelectric cell device (which may be referred to as the “photoelectric cell device 100” hereinafter) according to first-third embodiments of the present invention, the malfunction detecting approach according to the embodiments of the present invention will be described. An embodiment according to the present invention will be described below as a photoelectric cell device, though a photoelectric cell system could be also an embodiment according to the present invention.

### [1] Overview of Malfunction Detecting Approach According to Embodiments of Present Invention

As described above, various disadvantages could be found in photoelectric cell devices to which the typical techniques are applied (referred to as “typical photoelectric cell devices” hereinafter) because malfunction would be investigated and confirmed on the basis of information sent one after another from each power source module. For this, according to the embodiments of the present invention, the power source module included in the photoelectric cell device 100 selectively sends state information of the module. According to the embodiments of the present invention, the photoelectric cell device 100 further includes an inverter (also referred to as a power conditioner) for converting a direct-current power source applied through a power source line into a predetermined power source, and then the inverter attempts to detect malfunction in each power source module by collecting each of the state information.

The state information according to the embodiments of the present invention is information that indicates a state of a power source module. Using each of the state information, for example, the photoelectric cell device 100 may detect whether each power source module is normal, and may further detect what malfunction has been caused in a power source module detected not to be normal. The detection of malfunction by use of the state information according to the embodiments of the present invention may be performed by the inverter included in the photoelectric cell device or by an external device, for example. In the case where an external device detects malfunction by use of the state information, the inverter according to the embodiments of the present invention takes the role of collecting the state information and sending the collected state information to the external device, for example. The inverter included in the photoelectric cell device 100 may be a DC (Direct Current)/AC (Alternating Current) inverter for converting a direct-current power source into an alternate-current power source or a DC/DC inverter for converting a direct-current power source into another direct-current power source, though it is not limited thereto. It will be mainly described below the case where the inverter included in the photoelectric cell device 100 according to the embodiments of the present invention detects malfunction on the basis of the state information.

More specifically, in the photoelectric cell device 100, the inverter sends a request to transmit state information, and each of the power source modules selectively transmits its state information, based on the received information request. In the photoelectric cell device 100, identification information unique to each power source module (referred to as the “first identification information” hereinafter) is stored in each power source module, and the inverter sends the request that contains identification information (referred to as the “second identification information” hereinafter) specifying for which module to request to transmit its state information. Each power source module then determines whether to transmit its state information, based on the stored first identification information and the second identification information contained in the received information request. According to its determination, each power source module transmits its state information.

Thus, in the photoelectric cell device 100, particular power source modules requested to send their state information by an information request will send their state information, not like the typical techniques, where power source modules send their information one after another. In other words, in the photoelectric cell device 100, neither frequency signal nor pulse signal will necessarily be set uniquely for each power source module, not like the typical techniques, because the photoelectric cell device 100 may detect malfunction, based on the state information sent from the particular power source modules on the basis of the information request. Consequently, even if the number of the power source modules included in the photoelectric cell device 100 increases, the above-mentioned disadvantages of the typical techniques will not be found in the photoelectric cell device 100.

Further more, in the photoelectric cell device 100 according to the embodiments of the present invention, the power source modules apply their state information to power source lines (power-lines) at an attempt to detect malfunction on the basis of the state information. The respective currents flow through the power source lines, depending upon the photo-electromotive forces generated by the power source modules of the photoelectric cell device 100. More specifically, in the photoelectric cell device 100, the power source modules apply their state information to the power source lines within the respective power source modules, for example. And then, in the photoelectric cell device 100, the inverter, which is connected to the power source lines, collects the state information at an attempt to detect malfunction in each of the power source modules. Accordingly, if there is found a fall in resulting power, for example, the photoelectric cell device 100 may detect malfunction in each of the power source module separately, without any additional measures for specifying broken power source modules, such as measurements of an open voltage in the power source modules, a short-circuit current in the power source modules, etc.

In addition, in the photoelectric cell device 100, the inverter sends information requests to power source modules via the power source lines. Thus, the power source lines, through which the currents depending upon the photo-electromotive forces generated by the respective power source modules flow, take the role of communication paths between the inverter and the power source modules in the photoelectric cell device 100, respectively.

As described above, in the photoelectric cell device 100, information requests are sent from the inverter to the power source modules and state information is sent from the power source modules to the inverter via the power source lines as communication paths. Consequently, even if the number of the power source modules increases, the complicity of wiring in the photoelectric cell device 100 could be reduced in comparison to the case of the above-mentioned dedicated lines because the information requests and the state information can be transmitted and received without any dedicated line for each power source module.

Although the photoelectric cell device 100 according to the present invention has power source lines as communication paths in the exemplary explanation below, the communication paths in the photoelectric cell device will not necessarily be the power source lines. For example, even if dedicated lines are included therein for the respective power source modules, the photoelectric cell device 100 may facilitate detecting malfunction in the power source modules because the power source modules can selectively send their state information on the basis of information requests.

### [2] Exemplary States of Power Source Module According to Embodiments of Present Invention and Method of Detecting Thereof.

Next, there will be described exemplary states of a power source module according to the embodiments of the present invention and a method of detecting the states.

### [2-1] Exemplary States of Power Source Module

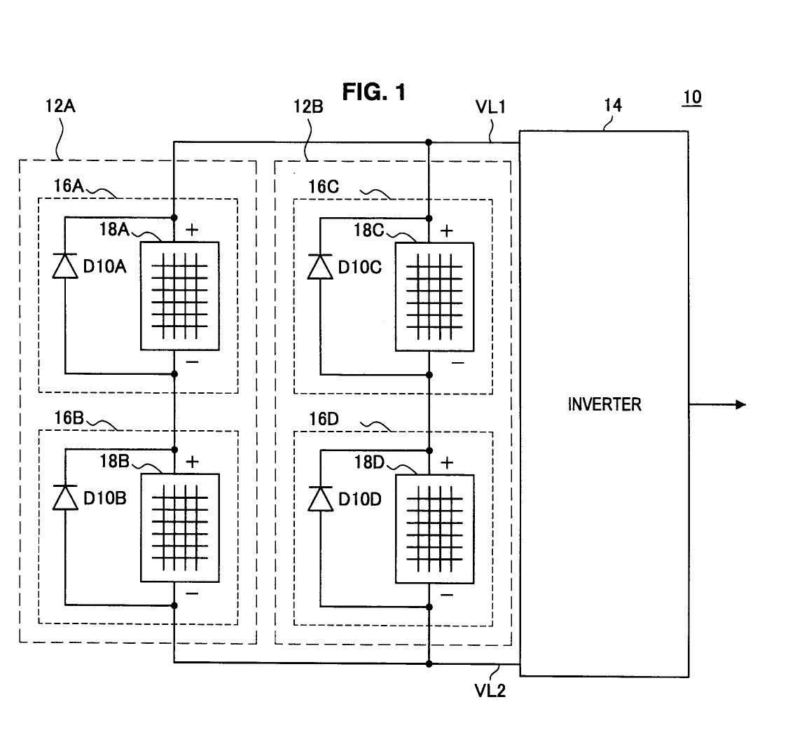

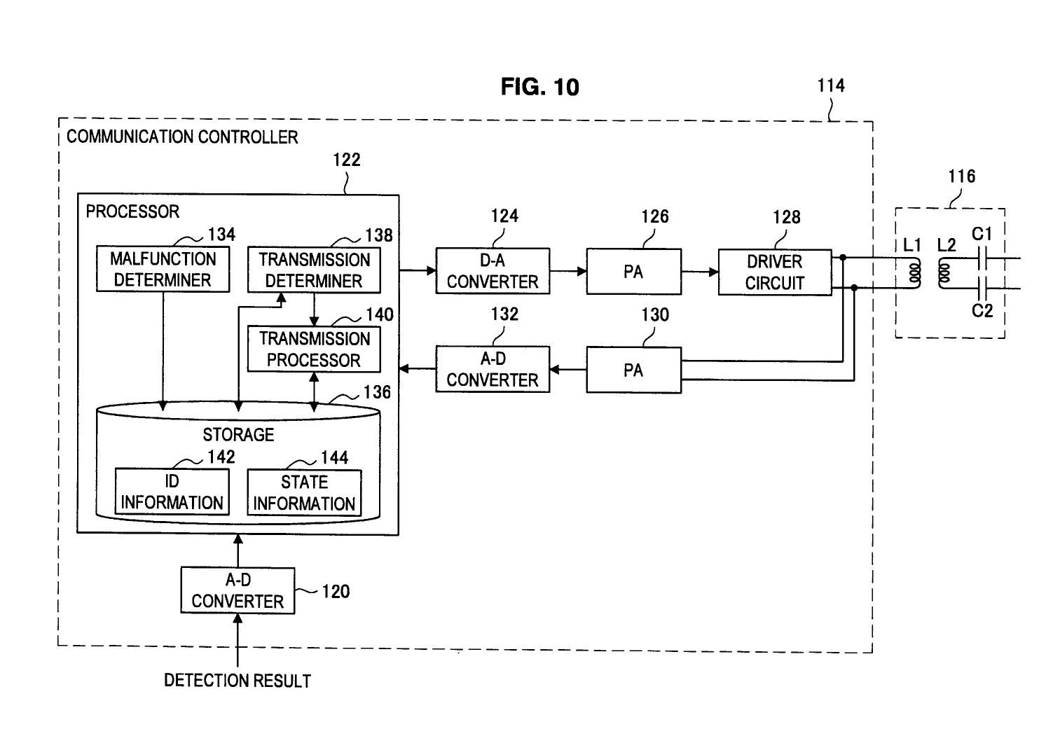

FIG. 1 is the first illustration for illustrating the state of the power source module according to the embodiments of the present invention. For the simplicity of the explanation below, a more general photoelectric cell device 10 is shown in FIG. 10, arranged differently from the photoelectric cell device 100, which will be described later. With the illustrative photoelectric cell device 10 shown in FIG. 1, there will be described below examples of the states of a power source module that may be detected by the photoelectric cell device 100.

In FIG. 1, the photoelectric cell device 10 includes power source units 12A and 12B between a power source line VL1 (power-line) and a ground line VL2. The photoelectric cell device 10 also include an inverter 14 connected to the power source line VL1 and the ground line VL2, respectively. In FIG. 1, the two power source units 12A and 12B (which may be referred to as the “power source units 12” hereinafter) are connected in parallel between the power source line VL1 and the ground line VL2, though they are not necessarily connected in such a manner.

The power source units 12 include one or more power source modules. For example, in FIG. 1, the power source unit 12A includes two power source modules 16A and 16B connected in series, and the power source unit 12B includes two power source modules 16C and 16D connected in series; namely, the power source units 12 shown in FIG. 1 falls into the direct formation.

Each of the power source modules 16A-16D (which may be collectively referred to as the “power source modules 16” hereinafter) included in the power source units 12 includes a photoelectric cell module (18A-18D shown in FIG. 1) and a bypass diode (D10A-D10D shown in FIG. 1).

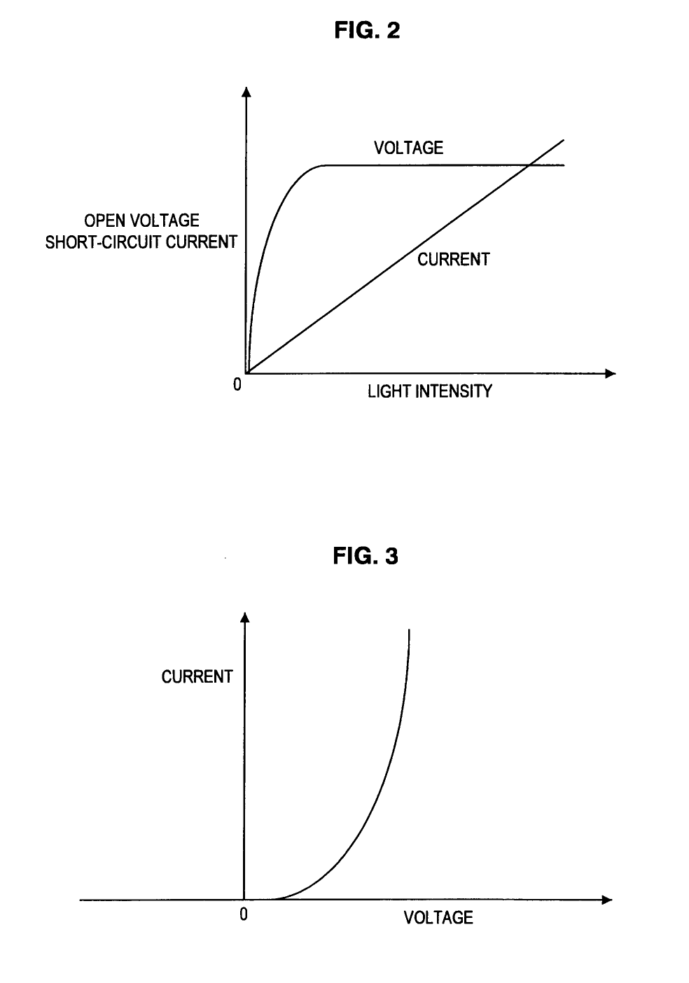

Each of the photoelectric cell modules 18A-18D (which may be collectively referred to as the “photoelectric cell modules 18” hereinafter) includes cells for generating photo-electromotive force from incident light, and the cells are connected in series and/or in parallel. FIG. 2 is an illustration that shows an example of the characteristic of a cell included in the photoelectric cell modules 18 of the power source modules 16 according to the embodiments of the present invention. As shown in FIG. 2, the cells included in photoelectric cell module 18 generate photo-electromotive force depending upon the intensity of incident light.

The anodes of the bypass diodes D10A-D10D (which may be collectively referred to as the “bypass diodes D10” hereinafter) are connected to the terminals on the sides of the ground line in the photoelectric cell modules 18, and the cathodes of the bypass diodes D10 are connected to the terminals on the sides of the poser source line in the photoelectric cell modules 18. For example, when open malfunction has been arisen in the photoelectric cell modules 18, the bypass diodes D10 take the role of forming bypasses to flow the currents (the currents flowing in dependence upon the photo-electromotive force of the other power source modules 16 connected in series). FIG. 3 is an illustration that shows an example of the characteristic of a bypass diode.

The power source modules 16 include the photoelectric cell modules 18 and the bypass diodes D10, for example. Next, states that might occur in the power source modules 16 will be described below. The states of the power source modules 16 shown below might be found in the power source modules included in the photoelectric cell device 100 according to the embodiments of the present invention.

### (i) Normal State

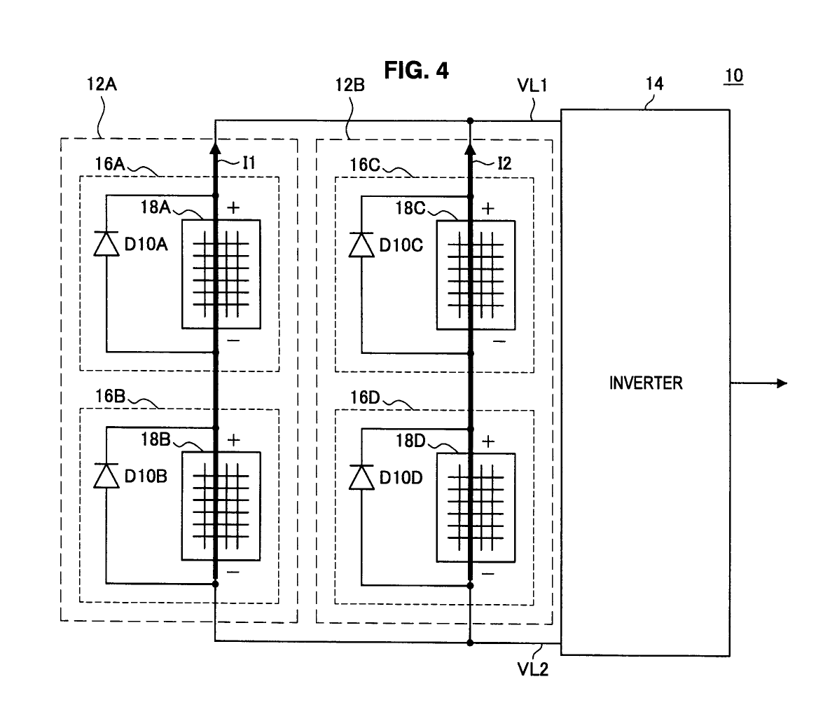

First of all, there will be shown the normal state, in which the power source modules are not broken. FIG. 4 is the second illustration for illustrating the state of the power source modules according to the embodiments of the present invention. FIG. 4 shows one situation where the power source modules 16 included in the photoelectric cell device 10 are in the normal states.

If the power source modules 16 are normal, the currents depending upon the photo-electromotive forces of the power source modules do not flow into the bypass diodes, but flow through the photoelectric cell modules (I1 and I2 in FIG. 4). This is because negative voltages are applied to the bypass diodes due to the electromotive forces of the power source modules 16. As shown in FIG. 3, no current flows through the bypass diodes if negative voltages are applied to the bypass diodes.

### (ii) First Malfunction State: Open Malfunction in Photoelectric Cell Modules 18

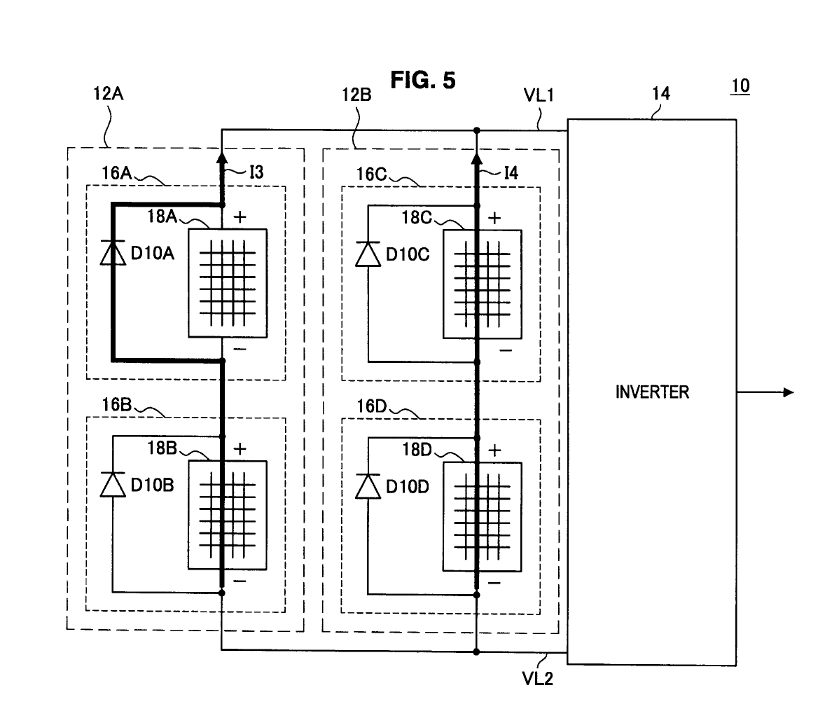

FIG. 5 is the third illustration for illustrating the state of the power source modules according to the embodiments of the present invention. FIG. 5 shows a situation where the photoelectric cell module 18A of the power source module 16A included in the photoelectric cell device 10 is found in open malfunction.

The resistance of the photoelectric cell module 18A in open malfunction will be infinite, and then the current I3 in FIG. 5 will avoid the power source module 16A and flow into the bypass diode D10A.

(iii) Second Malfunction State: Short-circuit Malfunction in Photoelectric Cell Modules 18

When the photoelectric cell modules 18 included in the power source modules 16 are found in short-current malfunction, the currents flowing into the power source modules 16 flows into the photoelectric cell modules 18, as shown in FIG. 4. This is because no current flows into the bypass diodes D10 to which negative voltages are applied, as shown in FIG. 3, when the photoelectric cell modules 18 are in short-circuit malfunction.

### (iv) Other States: No Incident Light on Some of Power Source Modules

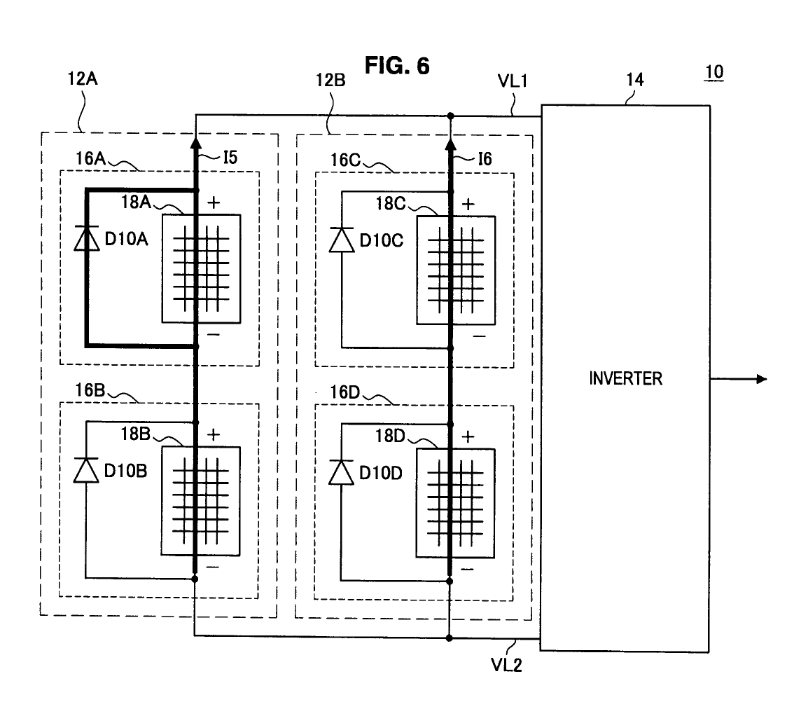

FIG. 6 is the forth illustration for illustrating the state of the power source modules according to the embodiments of the present invention. FIG. 6 shows one situation where no incident light is radiated over some of the power source modules 16. In FIG. 6, only the power source module 16A is not exposed to any incident light, and the photoelectric cell module 18 A does not generate photo-electromotive force.

When one of the power source modules, power source module 16A, is not exposed to any incident light, the voltage across the power source module 16A will not change remarkably, though the current flowing into the photoelectric cell module 18A will be reduced. Accordingly, if the current applied from the power source module 16B to the power source module 16A, which is connected to it in series, is larger than the current flowing into the photoelectric cell module 18A, then the current (I5 in FIG. 6) corresponding to the difference between these currents will flow into the bypass diode.

The states of (i) to (iv) as described above would be found in the power source modules 16, for example. The above states (i) to (iv) would also found in the power source modules included in the photoelectric cell device 100 according to the embodiments of the present invention.

### [2-2] State Detecting Method According to Embodiments of Present Invention

In the photoelectric cell device 100 according to the embodiments of the present invention, for example, the following values may be detected for each power source module:
Voltages across Photoelectric Cell Modules;
Currents Flowing into Photoelectric Cell Modules;
Voltages across Bypass Diodes;
Currents Flowing into Bypass Diodes; and
Voltages between Ground Line and Power-Source-Line-Side Terminals of Photoelectric Cell Modules.
   And then, state information based on the results of the detection may be stored. The photoelectric cell device 100 may detect the above states (i) to (iv) for each power source module, based on the state information selectively sent from each power source module. In short, the states (ii) or (iii) detected for a power source module in the photoelectric cell device 100 means malfunction of the power source module detected. Besides, it should be appreciated that the other measurements than the above-listed values could be also detected for power source modules according to the embodiments of the present invention.

The state (ii) (state of open malfunction) may be detected by detecting a current flowing into a bypass diode to confirm that a current flows into the bypass diode, for example. The state (iii) (state of short-circuit malfunction) may be detected by detecting a voltage across a photoelectric cell module and a voltage between the ground line and the terminal (the second terminal) on the power-source-line side of the photoelectric cell module, for example. The state (iv) (state of no incident light on power source module) may be detected on the basis of results of detecting a current flowing into a photoelectric cell module and results of detecting a current flowing the corresponding bypass diode, for example.

As described above, in the photoelectric cell device 100, the above-mentioned values are detected by each of the power source modules, for example, and state information indicating one of the above states (i) to (iv), into which each of the poser source modules is fall, is then stored. Now, as described above, the photoelectric cell device 100 sends information requests to the power source module, and the power source modules sends their state information selectively, based on the information requests. The photoelectric cell device 100 then detects malfunction for each power source module, based on the state information selectively sent from each power source module. Thus, even if there is found a fall in resulting power, for example, the photoelectric cell device 100 may detect malfunction in each of the power source module separately, without any additional measures for specifying broken power source modules.

Consequently, the photoelectric cell device 100 may facilitate detecting malfunction in power source modules.

Furthermore, even if the number of the power source modules included in the photoelectric cell device 100 increases, the above-mentioned disadvantages of the typical techniques will not be found in the photoelectric cell device 100, which can detects malfunction in power source modules on the basis of the state information. The photoelectric cell device 100 may thus achieve more flexible detection of malfunction in power source modules than the photoelectric cell devices to which the typical techniques are applied.

Next, there will be described the arrangement of the photoelectric cell device 100 according to the embodiments of the present invention, which device may achieve the malfunction detecting approach according to the embodiments of the present invention.

### (Photoelectric Cell Device According to Embodiments of Present Invention)

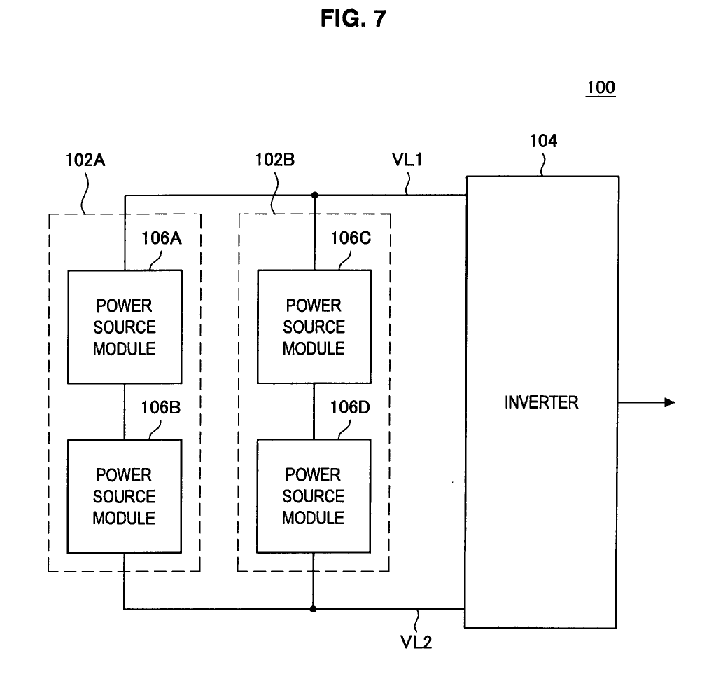

FIG. 7 is an illustration that shows an example of the arrangement of the photoelectric cell device 100 according to the embodiments of the present invention.

In FIG. 7, similarly to FIG. 1, the photoelectric cell device 100 includes two power source units 102A and 102B connected in parallel between a power source line VL1 (power-line) and a ground line VL2, though the photoelectric cell device 100 may be arranged differently. For example, the photoelectric cell device 100 may have one power source unit 102 between the power source line VL1 and the ground line VL2, or it may have more than two power source units 102 connected in parallel.

The power source unit 102A includes one or more power source modules. As the power source unit 102A, the power source unit 102B includes one or more power source modules. In FIG. 7, the power source unit 102A includes two power source modules 106A and 106B connected in series, and the power source unit 102B includes two power source modules 106C and 106D connected in series, though the power source units 102 may be arranged differently. The power source units 102A and 102B shown in FIG. 7 fall into the direct formation. Besides, the power source modules 106A to 106B included in the power source 102 may be collectively referred to as the power source modules 106 hereinafter.

The power source modules 106 generate photo-electromotive force from incident light. And also, the power source modules 106 apply, to the power source line VL1, state information that indicates the states of the power source modules 106. In this context, applications of state information to the power source line VL1 by the power source modules 106 corresponds to transmissions of the state information.

### [Exemplary Arrangement of Power Source Module 106]

### [1] First Exemplary Arrangement

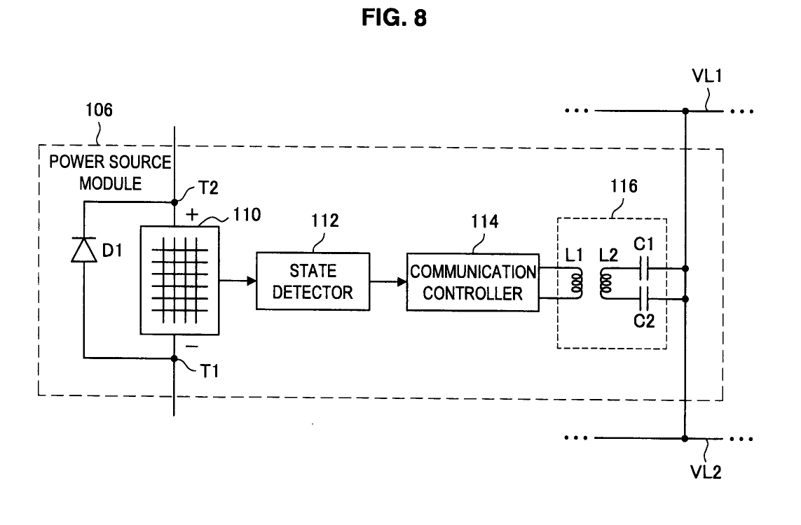

FIG. 8 is an illustration that shows the first exemplary arrangement of the power source module 106 according to the first embodiment of the present invention.

The power source module 106 includes a photoelectric cell module 110, a bypass diode D1, a state detector 112, a communication controller 114, and a communication unit 116.

The photoelectric cell module 110 includes cells for generating photo-electromotive force from incident light. The cells are connected in series and/or in parallel. In this context, a cell is the smallest unit of a device in the photoelectric cell device 100 for generating photo-electromotive force from incident light. A crystalline type cell functions as a device with the open voltage of about 0.55-0.60 [V] and the short-circuit current of about 25-30 [mA/cm²]. The cells included in the photoelectric cell module 110 generate photo-electromotive force depending upon the intensity of incident light, according to their characteristics as shown in FIG. 2, for example.

The anode of the bypass diode D1 is connected to the first terminal T1 on the ground-line side of the photoelectric cell module 110, and the cathode of the bypass diode D1 is connected to the second terminal T2 on the power-source-line side of the photoelectric cell module 110.

When open malfunction has been arisen in the photoelectric cell module 110, for example, the bypass diode D1 takes the role of forming a bypass to flow the current (the current flowing in dependence upon the photo-electromotive forces of the other power source modules 106 connected in series). If the photoelectric cell module 110 generates an electromotive force, or if the photoelectric cell module 110 has caused short-circuit malfunction, for example, no current flows into the bypass diode D1 because a negative voltage is applied to the bypass diode D1 (FIG. 4). On the contrary, if the photoelectric cell module 110 has caused open malfunction, for example, a current flows into the bypass diode D1 (FIG. 5). And also a current flows into the bypass diode D1 if some of the power source modules included in the power source unit 102 are not exposed to incident light, as described with reference to FIG. 6.

The state detector 112 detects the state of the power source module 106 and sends the result of the detection to the communication controller 114. In this context, the state of the power source module 106 detected by the state detector indicates whether the power source module 106 normally functions as a power source.

The state detector 112 may detect the following values for the power source module 106, for example:
Voltage across Photoelectric Cell Module 110;
Current Flowing into Photoelectric Cell Module 110;
Voltage across Bypass Diode D1;
Current Flowing into Bypass Diode D1; and
Voltages between Ground Line VL2 and Second Terminal T2.
   And then, the state detector 112 sends each of them as the result of the detection Besides, it should be appreciated that the other measurements than the above-listed values could be also detected by the state detector 112 according to the embodiments of the present invention.

### [Exemplary Arrangement of State Detector 112]

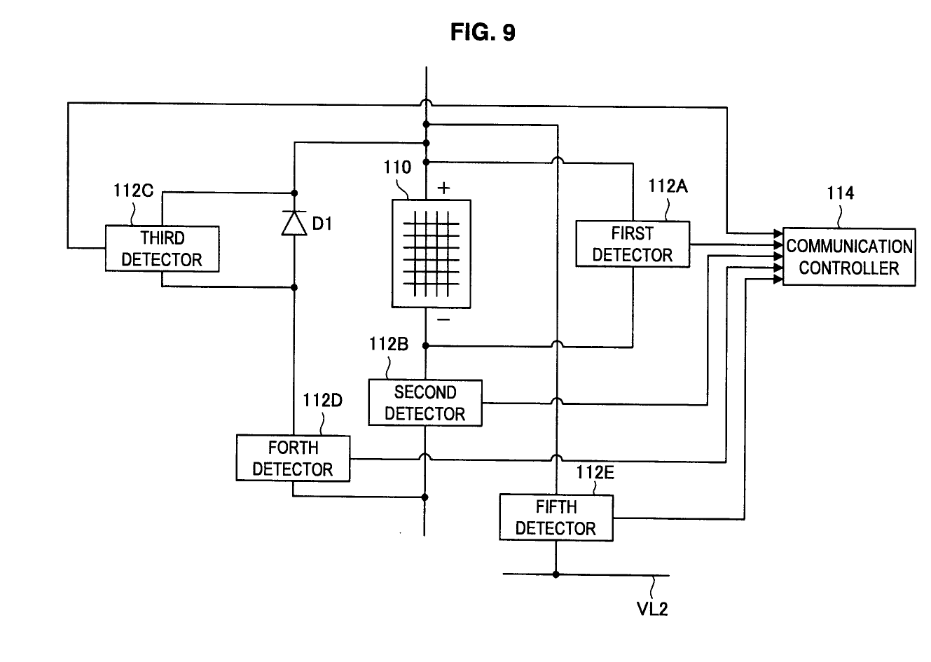

FIG. 9 is an illustration that shows an exemplary arrangement of the state detector 112 according to the embodiments of the present invention. FIG. 9 shows part of the power source module 106.

In FIG. 9, the state detector 112 includes a first detector 112A, a second detector 112B, a third detector 112C, a forth detector 112D, and a fifth detector 112E.

The first detector 112A includes a voltage detector to detect the voltage across the photoelectric cell module 110, for example. The second detector 112B includes a current detector to detect the current flowing into the photoelectric cell module 110, for example. The third detector 112C includes a voltage detector to detect the voltage across the bypass diode D1, for example. The forth detector 112D includes a current detector to detect the current flowing into the bypass diode D1, for example. And the fifth detector 112E includes a voltage detector to detect the voltage between the ground line VL2 and the second terminal T2, for example.

The state detector 112 may include the first to fifth detectors 112A to 112E as shown in FIG. 9 to detect the above-listed values, for exampled, and send each of these values to the communication controller 114 as the result of the detection.

The arrangement of the state detector 112 according to the embodiments of the present invention is not limited to the arrangement as shown in FIG. 9. For example, the state detector 112 according to the embodiments of the present invention may be arranged without the fifth detector 112E. With the state detector 112 even so arranged, the photoelectric cell device 100 may detect the states (i) to (iv) described above.

With reference to FIG. 8 again, the first exemplary arrangement of the power source module 106 is described here. State information based on the results of the detection sent from the state detector 112 is stored in the communication controller 114. The communication controller 114 controls the communication unit 116 to selectively transmit the state information, based on an information request received by the communication unit 116.

### [Exemplary Arrangement of Communication Controller 114]

FIG. 10 is an illustration that shows an exemplary arrangement of the communication controller 114 included in the power source module 106 according to the embodiments of the present invention. FIG. 10 shows the communication unit 116 as well.

The communication controller 114 includes an A-D (Analogue to Digital) converter 120, a processor 122, D-A (Digital to Analogue) converter 124, a PA (Power Amplifier) 126, a driver circuit 128, a PA 130, and A-D converter 132.

The A-D converter 120 converts the detection results (analogue signals) sent from the state detector 112 into digital signals. Besides, if the processor 122 can process an analogue signal, the A-D converter 120 may be not included in the communication controller 114.

The processor 122 includes MPUs (Micro Processing Units), various processing circuits, storages, etc. to determine the state of the power source module 106, based on the detection results sent from the A-D converter 120. For example, if the processor 122 determines that there has been caused malfunction, then state information is stored in the processor 122.

If a request to transmit the state information is detected, the processor 122 determines whether to transmit the state information, based on the second identification contained in the request for information and the first identification stored in the processor 122. The request is sent from the inverter 104 via the communication unit 116. And then, if the processor 122 determines to transmit the state information, it modulates the stored state information and controls the communication unit 116 to transmit the modulated state information.

In addition, the processor 122 includes a malfunction determiner 134, a storage 136, a transmission determiner 138, and a transmission processor 140. In FIG. 10, the processor 122 is arranged to include the storage 136, though the processor 122 may arranged differently. For example, the communication controller 114 may include the processor 122 and the storage 136 separately.

The malfunction determiner 134 determines whether there is malfunction, based on the detection results sent from the A-D converter 120. And for example, if it determines that there has occurred malfunction, it stores state information into the storage 136 selectively. The malfunction determiner 134 determines whether malfunction has occurred by threshold value processing by use of various results of the detection sent from the state detector 112 and data for determination corresponding to the various results of detection; though the way of determining is not limited thereto. The data for determination for use in threshold value processing by the malfunction determiner 134 may be stored in the storage 136 included in the processor 122, for example, though the data may be managed differently.

The malfunction determiner 134 stores the state information into the storage 136 in a data format which enables the information to contain multiple types of malfunction (e.g., open malfunction and short-circuit malfunction), though the format of the state information is not limited thereto. For example, the malfunction determiner 134 may store different pieces of state information into the storage 136 for different types of malfunction.

Additionally, the malfunction determiner 134 may not necessarily store the state information into the storage 136 selectively if it is determined that there has occurred malfunction. For example, the malfunction determiner 134 according to the embodiments of the present invention may store the state information into the storage 136, regardless of the determination based on the detection results sent from the A-D converter 120. In this case, state information which indicates one or more states of the above (i) to (iv) may be stored in the storage 136, for example.

The storage 136 is storage means included in the processor 122 for storing state information, the data for determination, ID information (first identification information) for the communication controller 114 to identify individual power source modules, etc. In FIG. 10, ID information 142 (first identification information) and a piece of state information 144 are stored in the storage 136, though the information to be stored is not limited thereto. The storage 136 may be a non volatile memory, such as an EEPROM (Electrically Erasable and Programmable Read Only Memory) or a flash memory, for example. However, it is not limited thereto.

The transmission determiner 138 determines whether an information request has been received from the inverter 104, based on digital signals sent from the A-D converter 132. If the transmission determiner 132 determines that an information request has been received, then it compares second identification information contained in the request for information with the ID information 142 (first identification information) stored in the storage 136. Depending upon the results of comparing the second identification with the ID information 142, the transmission determiner 138 selectively transmits to the transmission processor 140 an instruction to transmit the state information.

If the second identification contained in the request for information and the ID information 142 do not match, the transmission determiner 138 do not send to the transmission processor 140 an instruction to transmit the state information. Accordingly, in this case, the state information will not be transmitted from the power source module 106. If the second information contained in the request for information and the ID information 142 do match, then the transmission determiner 138 sends to the transmission processor 140 an instruction to transmit the state information. Accordingly, in this case, the state information will be transmitted from the power module 106.

When the instruction for transmission is issued by the transmission determination, the transmission processor 140 sends to the D-A converter 124 the state information stored in the storage 136. Otherwise, at this point, the transmission processor 140 may send to the D-A converter 124 the state information with the first identification information added. The transmission processor 140 may modulate (digital modulation) the state information stored in the storage 136 and send the modulated state information to the D-A converter 124, though the state information may be sent differently.

If no state information is stored in the storage 136 under the instruction for transmission issued, the transmission processor 140 may generate state information indicating that the power source module 106 is not broken and send it to the D-A converter 124, for example, though the transmission processor 140 may react differently.

Now, in the above explanation, the transmission determiner 138 sends the instruction for transmission to the transmission processor 140 selectively, and then the transmission processor 140 sends the state information in response to the instruction for transmission, though the mechanism of transmitting the state information is not limited in the above example. For example, in the processor 122 of the transmission controller 114 according to the embodiments of the present invention, the transmission determiner 138 may sends to the transmission processor 140 a result of comparing the second identification and ID information 142, and the transmission processor 140 may then send the state information selectively, based on the result of comparison.

Arranged as shown in FIG. 10, for example, the processor 122 may determine the state of the power source module 106, based on the detection results from the state detector 112. And then, state information indicating the state may be stored in the processor 122. Arranged as shown in FIG. 10, for example, the processor 122 may also have the communication unit 116 transmit the state information selectively, based on an information request received at the communication unit 116.

The D-A converter 124 converts the state information sent from the processor 122 into analogue signals. The PA 126 amplifies the state information sent from the D-a converter 124. The driver circuit 128 then applies the amplified state information sent from the PA 126 into a primary coil L1 of a transformer included in the communication unit 116 to transmit the state information.

The PA 130 amplifies signals sent from the primary coil L1 of the transformer included in the communication unit 116. The A-D converter 132 converts the signals (analogue signals) sent from the PA 130 into digital signals, and sends the signals to the processor 122. Besides, if the processor 122 can process an analogue signal, the A-D converter 132 may be not included in the communication controller 114.

Arranged as shown in FIG. 10, for example, the communication controller 114 may selectively transmit the state information on the basis of the detection results sent from the state detector 112, based on the request for information sent from the inverter 104. Besides, it should be appreciated that the communication controller 114 according to the embodiments of the present invention may be arranged differently from the arrangement shown in FIG. 10.

The communication controller 114 is driven by the photoelectric cell module 110 included in the power source module 106 as its power source. Now, the photoelectric cell module 110 has cells connected in series and/or in parallel. Accordingly, the communication controller 114 may be driven by one of or each of the cells included in the photoelectric cell module 110 as its power source. Supplied with power by the multiple cells, the communication controller 114 may enjoy higher probability to be supplied with enough power to drive even if one of the cells happened to be in open malfunction.

Besides, it should be appreciated that the communication controller 114 may be driven by any power supplied by another power source module, a separately-provided internal power source, or an external power source. Such a internal power source could be, for example, a secondary battery, such as a lithium ion secondary battery, a lithium ion polymer secondary battery, etc., though it is not limited thereto.

With reference to FIG. 8 again, the first exemplary arrangement of the power source module 106 according to the embodiments of the present invention is described here. The communication unit 116 includes a transformer to apply the state information to the power source line VL1. With the communication 116, the power source module 106 may transmit the state information by putting the state information onto a current depending upon the photo-electromotive force of the power source unit 102.

The primary coil L1 included in the transformer is connected to the communication controller 114. Then, the secondary coil L2 included in the transformer is connected to the power source line VL1 and the ground line VL2, for example.

Arranged as shown in FIG. 8, for example, the power source module 106 may generate photo-electromotive force from incident light and apply the state information (i.e., transmit the state information) to the power source line VL1 selectively, based on an information request.

### [2] Second Exemplary Arrangement

As described above, in the first exemplary arrangement of the power source module 106, the secondary coil L2 of the transformer included in the communication unit 116 is connected to the power source line VL1 and the ground line VL2. The power source module 106 according to the embodiments of the present invention may yet be arranged differently from the arrangement shown in FIG. 8.

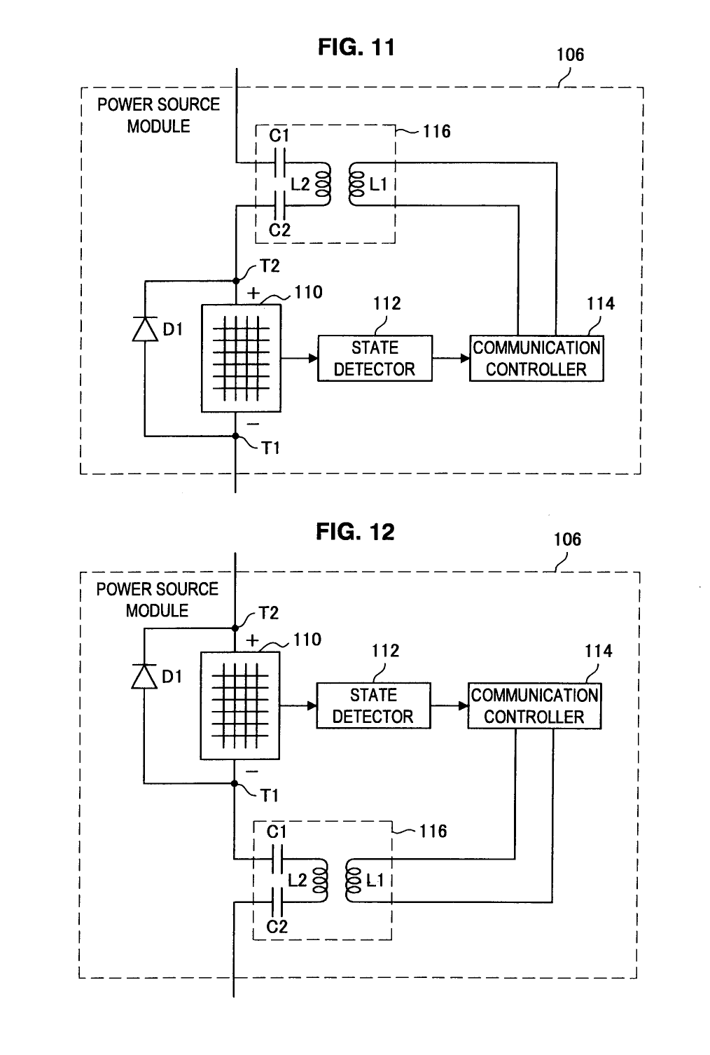

FIG. 11 is an illustration that shows the second exemplary arrangement of the power source module 106 according to the first embodiment of the present invention.

According to the second exemplary arrangement, the power source module 106 is arranged similarly to the power source module 106 shown in FIG. 8; however, in the second exemplary arrangement, state information is applied by the communication unit 116.

As in the communication unit 116 according to the first exemplary arrangement, the communication unit 116 according to the second exemplary arrangement includes a transformer to apply the state information to the power source line VL1 (more specifically, to a power source line included in the power source module for conveying the current depending upon the electromotive force of the power source unit 102 to the power source line VL1).

The primary coil L1 included in the transformer is connected to the communication controller 114. And, the secondary coil L2 included in the transformer is connected to the wire leading from the second terminal T2 to the power source line VL1, for example. Thus, state information controlled to be selectively sent by the communication controller 114 is put onto a current flowing through the power source line within the power source module, which power source line is arranged to convey the current depending upon the electromotive force of the power source unit 102 to the power source line VL1. As a result, the state information will be applied to the power source line VL1 accordingly.

With the communication 116 according to the second exemplary arrangement, the power source module 106 may transmit the state information by putting the state information onto the current depending upon the photo-electromotive force of the power source unit 102, as in the communication 116 according to the first exemplary arrangement.

### [3] Third Exemplary Arrangement

FIG. 12 is an illustration that shows the third exemplary arrangement of the power source module 106 according to the first embodiment of the present invention.

According to the third exemplary arrangement, the power source module 106 is arranged similarly to the power source module 106 shown in FIG. 8; however, in the third exemplary arrangement, state information is applied by the communication unit 116.

As in the communication unit according to the first exemplary arrangement, the communication unit 116 according to the third exemplary arrangement includes a transformer to apply the state information to the power source line VL1 (more specifically, to a power source line included in the power source module for conveying the current depending upon the electromotive force of the power source unit 102 to the power source line VL1).

The primary coil L1 included in the transformer is connected to the communication controller 114. And, the secondary coil L2 included in the transformer is connected to the wire leading from the first terminal T1 to the ground line VL2, for example. Thus, state information controlled to be selectively sent by the communication controller 114 is put onto a current flowing through the power source line within the power source module, which power source line is arranged to convey the current depending upon the electromotive force of the power source unit 102 to the power source line VL1. As a result, the state information will be applied to the power source line VL1 accordingly.

With the communication 116 according to the third exemplary arrangement, the power source module 106 may transmit the state information by putting the state information onto the current depending upon the photo-electromotive force of the power source unit 102, as in the communication 116 according to the first exemplary arrangement.

Arranged as shown in FIG. 8, FIG. 11, or FIG. 12, for example, the power source module 106 may generate photo-electromotive force from incident light. And also, arranged as shown in FIG. 8, FIG. 11, or FIG. 12, for example, the power source module 106 may selectively apply, to the power source line VL1, the state information which indicates the state of the power source module 106, based on an information request sent from the inverter 104. Besides, it should be appreciated that the power source module 106 according to the embodiments of the present invention may be arranged differently from the arrangements shown in FIG. 8, FIG. 11, and FIG. 12.

With reference to FIG. 7 again, the components of the photoelectric cell device 100 are described here. The inverter 104 is connected to the power source line VL1 and the ground line VL2, and takes the role of converting a direct-current power source applied from the power source line VL1 into a predetermined power source to supply the converted power source to an external device.

In addition, the inverter 104 selectively sends, to each power source module 106 via the power source line VL1, a request (data) to transmit its state information.

### [Exemplary Arrangement of Inverter 104 for Transmitting Request for Information]

With a storage (not shown), a transmission scheduler (not shown), and a transmission processor (not shown) included therein, for example, the inverter 104 transmit an information request selectively (scheduled transmission). In the inverter 104, an integrated circuit for various processes, such as an MPU, a modulator circuit, etc., may take the roles of the transmission scheduler (not shown) and an information request transmission processor (not shown), though the roles may be taken by something else.

In the storage (not shown), there are stored the second identification information corresponding to each of the power source module 106 included in the photoelectric cell device 100, process programs for transmitting an information request, etc. The storage (not shown) may be a non volatile memory, such as an EEPROM, a flash memory, etc., though it is not limited thereto.

The transmission scheduler (not shown) sets a schedule for transmitting an information request (a plan for acquiring) in order to acquire state information from each of the power source modules. For example, the transmission scheduler (not shown) may set the transmission schedule for each power source module 106, based on information about various conditions related to incident light over the power source module 106, such as information of date and time, information of the weather, etc, though the basis is not limited to such information. The information about various conditions related to incident light over the power source module 106 may acquired from a clock included in the inverter 104, from an external device via a network, or elsewhere.

The transmission processor (not shown) determines whether to transmit an information request, based on the transmission schedule set by the transmission scheduler (not shown). If the transmission processor (not shown) determines to transmit an information request, it reads from the storage (not shown) second identification information corresponding to a power source module to send its state information in response to the request for information, and generates the request for information with the second identification information contained therein. The transmission processor (not shown) transmits the generated request for information by applying it to the power source line VL1.

With the storage (not shown), the transmission scheduler (not shown), and the transmission processor (not shown) included therein, the inverter 104 may realise selective transmission of the request for information (scheduled transmission). Besides, it should be appreciated that an information request may be transmitted differently by the differently arranged inverter 104 according to the embodiments of the present invention.

The inverter 104 then receives the state information via the power source line VL1. The inverter 104 may function to detect malfunction of each power source module on the basis of the received state information, though malfunction may be detected on a different basis.

### [Exemplary Arrangement of Inverter 104 for Detecting Malfunction on Basis of State Information]

The inverter 104 may function to detect malfunction, including, for example, a filter circuit (not shown) for detecting the state information, a processor circuit (not shown) for processing determination for an output from the filter circuit to determine that there has occurred malfunction, etc. The inverter 104 may further include a communication circuit (not shown) for transmit information of detected malfunction to an external device in wired/wireless communication.

Thus, an information request is sent on the basis of the transmission schedule, and state information is transmitted from the power source module 106 in response to the sent request for information. The processor circuit (not shown) detects determines the state of the power source module by the state information to detect malfunction, though it may detect malfunction differently. For example, if no state information from the expected power source module 106 has been detected in a given time duration after the request for information has been sent on the basis of the transmission schedule, the processor circuit (not shown) may determine that the power source module 106 is broken. The above-mentioned given time duration may be preset, or otherwise optionally set by a user or a manager of the photoelectric cell device 100. The given time duration is stored in the storage (not shown), for example, to be referred by the processor circuit (not shown) in any appropriate occasions, though it may be managed differently. Thus, even if the communication controller 114 is not supplied with power due to the malfunction in the photoelectric cell module 110 of the power source module 106, the photoelectric cell device 100 may detect malfunction of the power source module 106.

With the filter circuit (not shown), the processor circuit (not shown), etc. included therein, the inverter 104 may function to detect malfunction of each power source module, based on the received state information. Besides, it should be appreciated that malfunction may be detected differently by the differently arranged inverter 104 according to the embodiments of the present invention

Alternatively, the inverter 104 may take the role of sending the received state information to an external device which can detect malfunction (i.e., the inverter 104 relays the state information). With a filter circuit (not shown) and a communication circuit (not shown) included therein, the inverter 104 may relay the state information.

Arranged as shown in FIG. 7, for example, the photoelectric cell device 100 may achieve the above-described malfunction detecting approach according to the embodiments of the present invention.

As described above, in the photoelectric cell device 100 according to the embodiments of the present invention, each of the power source modules 106 detects its state, and its state information which indicates one of the above-mentioned possible states (i) to (iv) of the power source module 106 is stored in the power source module 106. Furthermore, in the photoelectric cell device 100, an information request is sent to the power source module 106, according to the transmission schedule set by the inverter 104. Each power source module 106 then transmits its state information selectively, based on the request for information. Then, the photoelectric cell device 100 detects malfunction for each power source module, based on the state information selectively transmitted from each power source module 106. Thus, if there is found a fall in resulting power, for example, the photoelectric cell device 100 may detect malfunction for each power source module, without any additional measures for specifying broken power source modules, such as measurements of an open voltage in the power source modules 106, a short-circuit current in the power source modules 106, etc. Consequently, the photoelectric cell device 100 may facilitate detecting malfunction in power source modules.

The photoelectric cell device 100 detects malfunction of a power source module 106, based on the state information transmitted from the particular power source module 106 corresponding to an information request. Thus, even if the number of the power source modules 106 included in the photoelectric cell device 100 increases, the above-mentioned disadvantages of the typical techniques will not be found in the photoelectric cell device 100. Consequently, the photoelectric cell device 100 may achieve more flexible detection of malfunction in power source modules than the typical photoelectric cell devices to which the typical techniques are applied may.

Furthermore, the photoelectric cell device 100 may collect information of various aspects of malfunction for each power source module by the state information applied to the power source line VL1. Accordingly, the photoelectric cell device 100 may reduce the costs of managing the photoelectric cell device 100 (or the photoelectric cell system).

Although the photoelectric cell device 100 has been described as an example of the embodiments of the present invention, the embodiments of the present invention is not limited thereto. The embodiments of the present invention may be applied to various systems and machines which can generate photo-electromotive force from incident light, such as a solar cell system (a solar cell device) which is capable of generating power from the sunlight.

### (Malfunction Determining Method According to Embodiments of Present Invention)

As described above, the photoelectric cell device 100 according to the embodiments of the present invention may function to detect malfunction in power source modules 106, based on state information. Now, on the assumption that the photoelectric cell device 100 functions to detect malfunction in power source modules, a method of detecting the malfunction will be described next.

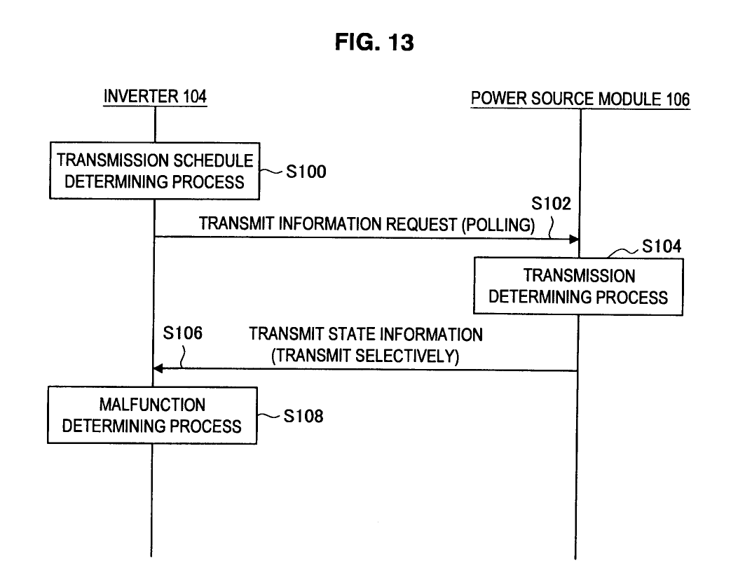

FIG. 13 is an illustration that shows an example of the malfunction determining method of the photoelectric cell device 100 according to the embodiments of the present invention. In FIG. 13, the inverter 104 detects and determines malfunction of one power source module 106 included in the photoelectric cell device 100, based on the communication between the inverter 104 and the power source module 106. Besides, malfunction of the rest of the power source modules 106 will not described in detail here since their malfunction may be determined similarly to the malfunction of the above power source module 106 by the photoelectric cell device 100 according to the embodiments of the present invention.

The inverter 104 and the power source module 106 shown in FIG. 13 communicate with each other via the power source line VL1, though they may communicate with each other differently. For example, the inverter 104 and the power source module 106 may communicate with each other via a dedicated line for connecting the inverter 104 to the each of the power source modules 106.

The inverter 104 determines whether to transmit an information request to the power source module 106 to transmit its state information (S100: Transmission Schedule Determination Process). The inverter 104 will not transmit an information request if it determines not to transmit the request for information in step S100.

And if the inverter determines to transmit an information request in step S100, then it transmits the request for information (S102). In this context, transmitting the request for information in step S102 corresponds to polling.

The power source module 106 receives the request for information transmitted from the inverter 104 in step S102, and then determines whether to transmit its state information, based on the received request for information (S104: Transmission Determining Process). At this point, the power source module 106 (or more specifically, the communication controller 114 included in the power source module 106) conducts the determination in step S104 by, for example, comparing the second identification information contained in the request for information to the first identification information stored in the power source module 106.

Besides, the power source module 106 might not be able to conduct the detection in step S104 if, for example, open or short-circuit malfunction has occurred in the photoelectric cell module 110 included in the power source module 106. Even in this case, in step S108 to be described later, the inverter 104 may determine whether any malfunction has occurred in the power source module 106.

The power source module 106 will not transmit its state information if it determines not to transmit the state information in step S104. Otherwise, if the power source module 106 determines to transmit the state information in step S104, it transmits the state information (S106). Thus, transmission of the state information in step S106 can be said to be selective transmission based on the request for information.

The inverter 104 determines whether there has occurred malfunction in the power source module 106 (S108: Malfunction Determining Process), based on the state information transmitted from the power source module 106 in step S106. The state information transmitted from the power source module 106 indicates one of the above-described states (i) to (iv), for example. Thus, the inverter 104 may recognise the state of the power source module 106 on the basis of the state information, and accordingly, the inverter may determine the occurrence of malfunction in the power source module and the type thereof.

In addition, if no state information from the expected power source module 106 has been detected in a given time duration after the request for information has been transmitted in step S102, the inverter 104 may determine that the power source module is broken (in open malfunction, short-circuit malfunction, etc.). Thus, the inverter 104 may detect malfunction in the power source module even if no state information has been transmitted from the power source module 106 due to the malfunction in the photoelectric module 110 of the power source module 106, for example.

By the inverter 104 and each power source module 106 communicating to each other for conducting the processes as shown in FIG. 13, the photoelectric cell device 100 may detect and determine malfunction of each of the power source modules 106. Besides, it should be appreciated that the malfunction determining method of the photoelectric cell device 100 according to the embodiments of the present invention is not limited to the processes described above.

It should be understood by those skilled in the art that various modifications, combinations, sub-combinations and alterations may occur depending on design requirements and other factors insofar as they are within the scope of the appended claims or the equivalents thereof.

The present application contains subject matter related to that disclosed in Japanese Priority Patent Application JP 2009-028434 filed in the Japan Patent Office on 12 Feb. 2009, the entire content of which is hereby incorporated by reference.

What is claimed is:

1. A photoelectric cell device comprising:
a power source unit arranged between a ground line and a power source line for generating an photo-electromotive force from incident light and applying, to the power source line, state information which indicates a state; and
an inverter for converting a direct-current power source applied from the power source line into a predetermined power source and communicating with the power source unit via the power source line,
wherein the power source unit includes one or more power source modules, each of which includes
a photoelectric cell module including
cells arranged in series and/or in parallel for generating the photo-electromotive force from the incident light,
a first terminal on a side of the ground line, and
a second terminal on a side of the power source line,
a bypass diode having an anode and a cathode, the anode being connected to the first terminal of the photoelectric cell module, the cathode being connected to the second terminal of the photoelectric cell module,
a state detector for detecting a state of the each of the power source modules and outputting the detected state as a detection result,
a communication unit for receiving an information request from the inverter and applying the state information based on the detection result to the power source line, and
a communication controller for controlling the communication unit to apply the state information selectively, based on the information request received by the communication unit.

2. The photoelectric cell device according to claim 1, wherein the communication controller has first identification information stored therein for uniquely representing the each of the one or more power source modules and controls the communication unit to transmit the state information if the first identification information matches second identification information specifying one or more of the one or more power source modules requested to transmit the state information, the second information being contained in the information request.

3. The photoelectric cell device according to claim 2, the communication controller controls the communication unit not to transmit the state information if the first identification information does not match the second identification information.

4. The photoelectric cell device according to claim 1,
wherein the communication unit includes a transformer having
a primary coil arranged to connect to the communication controller and
a secondary coil arranged between the second terminal and the power source line or between the first terminal and the ground line.

5. The photoelectric cell device according to claim 1,
wherein the communication unit includes a transformer having
a primary coil arranged to connect to the communication controller and
a secondary coil arranged to connect to the ground line and the power source line.

6. The photoelectric cell device according to claim 1, wherein the communication controller is powered by the photoelectric cell module.

7. The photoelectric cell device according to claim 6, wherein the communication controller is powered by each one or more of the cells included in the photoelectric cell module.

8. A malfunction determining method comprising the steps of:
transmitting an information request to a power source unit in order to acquire state information which indicates a state, the power source unit being arranged between a ground line and a power source line for generating an photo-electromotive force from incident light, the power source unit including one or more power source modules, each of which selectively applies the state information to the power source line on a basis of the information request; and
determining a state of the each of the one or more power source module, based on the state information selectively applied to the power source line.
